(19) United States
(12) Patent Application Publication
(10) Pub. No.: US 2010/0295560 A1
(43) Pub. Date: Nov. 25, 2010

(54) Scanning Impedance Microscopy (SIM) To Map Local Impedance In A Dielectric Film

(76) Inventor: Quan Tran, Fremont, CA (US)

Correspondence Address: INTEL CORPORATION;c/o CPA Global, P.O. BOX 52050, MINNEAPOLIS, MN, 55402, US

(21) Appl. No.: 12/242,730

(22) Filed: Sep. 30, 2008

(51) Int. Cl. G01R 27/26; G01R 27/08

(52) U.S. Cl. 324/661; 324/709

(57) ABSTRACT

A scanning impedance microscopy device maps out local impedance in a dielectric film sample. This may be used to detect conductive filaments in a dielectric film, to characterize semiconductor interfaces, and to be used a reading scheme for resistive change memory such as RRAM.

### FIELD OF THE INVENTION

Embodiments of the present invention are directed to mapping local impedance in a dielectric film and, more particularly, to techniques to detect conductive filaments in a dielectric film such as may be used in a resistive change random access memory (RRAM).

### BACKGROUND INFORMATION

Conventional solid state memories employ microelectronic circuit elements for each memory bit. Since one or more electronic circuit elements are required for each memory bit (e.g., one to four transistors per bit), these devices can consume considerable chip “real estate” to store a bit of information, which limits the density of a memory chip. The primary memory element in these devices is typically a floating gate field effect transistor device that holds a charge on the gate of field effect transistor to store each memory bit. Typical memory applications include dynamic random access memory (DRAM), static random access memory (SRAM), erasable programmable read only memory (EPROM), and electrically erasable programmable read only memory (EEPROM).

A different type of solid state memory commonly known as a phase-change memory uses a phase-change material as the data storage mechanism and offers significant advantages in both cost and performance over conventional memories based on charge storage. Phase change memories use phase change materials—in other words, materials that can be electrically switched between two or more phases having different electrical characteristics such as resistance. One type of memory element, for example, uses a phase change material that can be electrically switched between a generally amorphous phase and a generally crystalline local order, or between different detectable phases of local order across the entire spectrum between completely amorphous and completely crystalline phases.

The phase-change memory can be written to, and read from, by applying current pulses that have the appropriate magnitude and duration and that cause the needed voltages across and current through the volume of phase change material. A selected cell in a phase-change memory can be programmed into a selected state by raising a cell voltage and a cell current for the selected cell to programming threshold levels that are characteristic of the phase-change material. The voltage and current are then typically lowered to quiescent levels (e.g. essentially zero voltage and current) that are below the programming threshold levels of the phase-change material. This process can be performed by the application of, for example, a reset pulse and a set pulse which can program the cell into two different logic states. In both of these pulses, the cell voltage and cell current are caused to rise at least as high as certain threshold voltage and current levels needed to program the cell.

Next, to read the programmed cell, a read pulse can be applied to measure the relative resistance of the cell material, without changing its phase. Thus, the read pulse typically provides a much smaller magnitude of cell current and cell voltage than either the reset pulse or the set pulse.

These electrical memory devices typically do not use field effect transistor devices, but comprise, in the electrical context, a monolithic body of thin film material. As a result, very little chip real estate is required to store a bit of information, thereby providing for inherently high density memory chips. The phase change materials are also truly non-volatile in that, when set in either a crystalline, semi-crystalline, amorphous, or semi-amorphous phase representing a resistance value, that value is retained until reset as that value represents a physical phase of the material (e.g., crystalline or amorphous).

### BRIEF DESCRIPTION OF THE DRAWINGS

The foregoing and a better understanding of the present invention may become apparent from the following detailed description of arrangements and example embodiments and the claims when read in connection with the accompanying drawings, all forming a part of the disclosure of this invention. While the foregoing and following written and illustrated disclosure focuses on disclosing arrangements and example embodiments of the invention, it should be clearly understood that the same is by way of illustration and example only and the invention is not limited thereto.

FIGS. 1A-1C are diagrams showing an illustrative SSP memory device and its basic operation;

FIG. 2 is a block diagram showing a set up for mapping filaments or conductive paths in a dielectric film such as Lead Zirconate Titanate (PZT);

FIG. 3 is a block diagram showing a current signal at a location that is not a conductive filament;

FIG. 4 is a block diagram showing the current signal at a filament and its corresponding vector diagram;

FIG. 5 is a block diagram showing a set up for mapping a metal/semiconductor interface;

FIG. 6A is a plot showing a scanning impedance microscopy (SIM) image of a 1 um×1 um area on a PZT sample when the DC source is 1V and AC source amplitude is 250 mVp-p at 66 Hz;

FIG. 6B is a plot showing a scanning impedance microscopy (SIM) image of a 1 um×1 um area on a PZT sample when the DC source is 2V and AC source amplitude is 250 mVp-p at 66 Hz; and

FIG. 6C is a plot showing a scanning impedance microscopy (SIM) image of a 1um×1 um area on a PZT sample when the DC source is 3V and AC source amplitude is 250 mVp-p at 66 Hz..

### DETAILED DESCRIPTION

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

A type of phase change memory is the so-called seek-scan probe (SSP) memories which are a type of memory that uses non-volatile storage media as the data storage mechanism and offers significant advantages in both cost and performance over conventional charge-storage memories. Typical SSP memories include storage media made of materials that can be electrically switched between two or more states having different electrical characteristics such as resistance, polarization dipole direction, or some other characteristic.

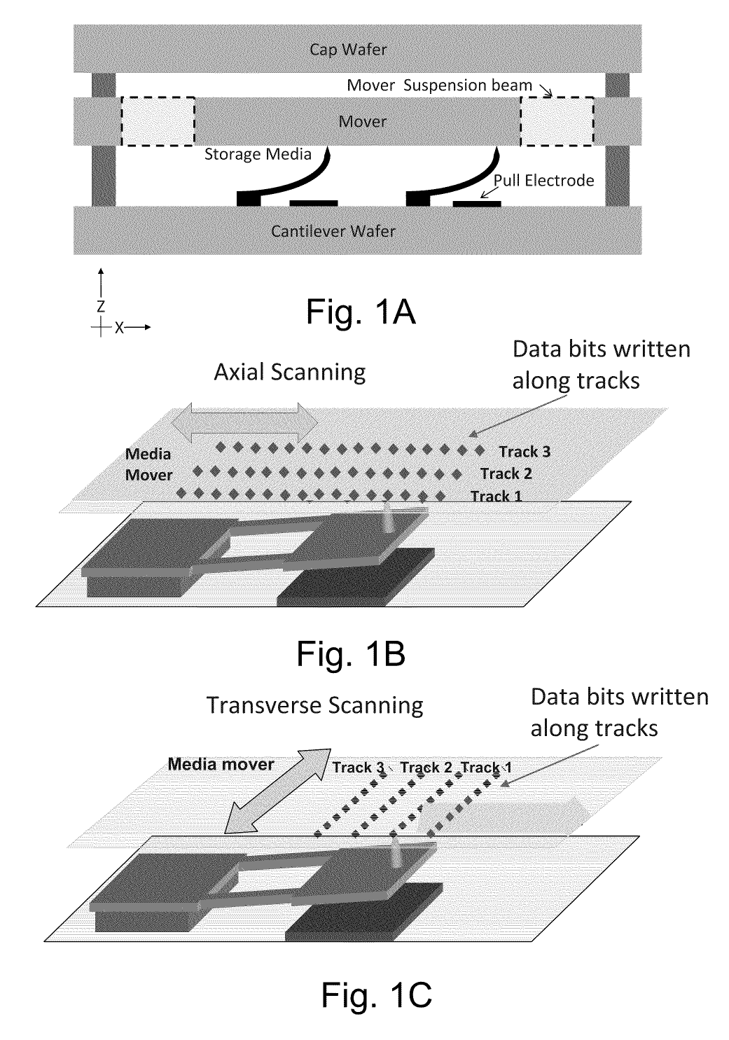

FIGS. 1A-1C illustrate tracking in a common SSP memory configuration. FIG. 1A illustrates an SSP memory configuration in which a cantilever probe is anchored to a substrate (the cantilever wafer), and can be actuated to contact or de-contact the storage media on a mover that carries a storage media and is positioned over the cantilever wafer. The data tracks are stored in the storage media in one of two ways, depending on how the media mover scans relative to the cantilever tips.

FIG. 1B illustrates axial scanning, where data is stored in the storage media in-line with the cantilever direction, such that the mover scans in the direction parallel to a longitudinal axis of the cantilever to read/write/erase (R/W/E) each data track.

FIG. 1C illustrates transverse scanning, where the media mover scans in a direction perpendicular to the longitudinal axis of the cantilever probe to R/W/E each data track; data is consequently stored in lines that are transverse to the cantilever's longitudinal axis. To maximize the amount of data that can be written in the storage media the data density should be very high.

In the case of a resistive change random access memory (RRAM), the media layer or phase change layer may be a dielectric material such as PZT, for example. The dielectric material, which is normally insulating, can be made to conduct through a conduction path, sometimes called a “conductive filament” formed by application of a sufficiently high voltage. This filament may be detected or read, for example, by a cantilevered probe and may represent a bit of data depending on its current state of being high resistance or low resistance. It is believed that the conduction filament formation may be formed by different mechanisms, including defects, metal migration, etc. Once the filament is formed, it may be broken, resulting in high resistance, or re-formed, resulting in lower resistance, over and over again by an appropriately applied voltage.

Embodiments of the invention describe a technique to map out local impedance in a dielectric film sample. This may be used to detect conductive filaments in a dielectric film, to characterize semiconductor interfaces, and to be used a reading scheme for resistive change memory such as RRAM.

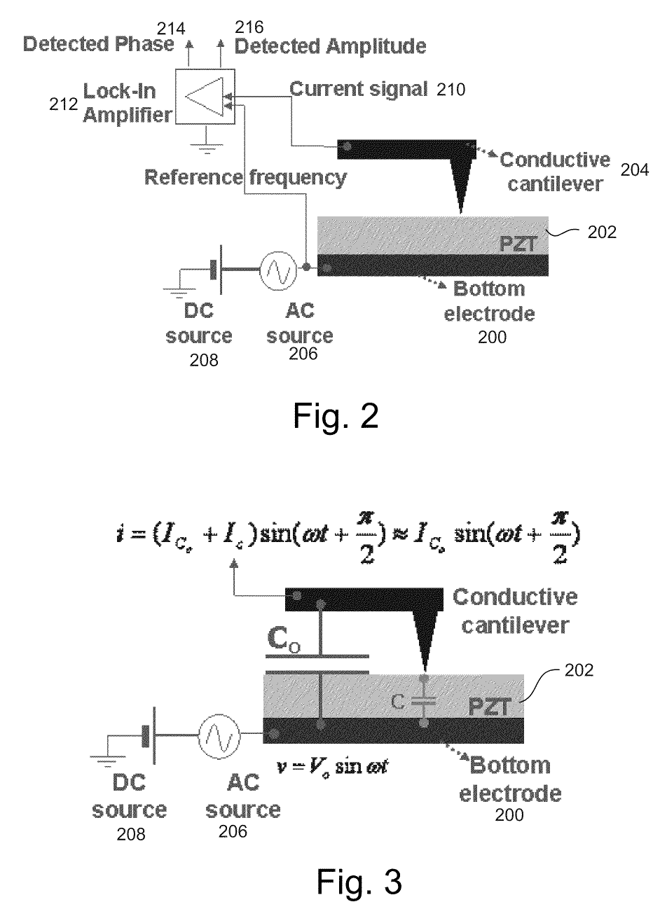

Referring now to FIG. 2, there is shown a setup to detect conductive filaments in a film. As shown a media comprising a bottom electrode 200 over which there is deposited a film 202, such as PZT. A conductive cantilever and probe 204 may be used to scan over the surface of the film 202. An alternating current (AC) source 206 may be applied to the bottom electrode 200. The AC source 206 may be biased by a direct current (DC) source 208 to apply a bias voltage to the bottom electrode 200.

The configuration shown in FIG. 2 may be used to detect conductive filaments in the PZT film 202. The AC source 206 applies an AC voltage to bottom electrode 200 which generates a current signal 210 on the conductive cantilever 204. The current signal 210 is fed into a lock-in amplifier 212 to compare with the AC voltage source 206. The lock-in amplifier 212 outputs detected phase 214 and detected amplitude 216 of the current signals. From these detected phase and amplitude of the current signals, impedance of the PZT film 202 may be mapped out as the cantilever 204 scans over an area.

FIG. 3 shows to set-up of FIG. 2 showing a current signal at a location in the PZT film 202 that is not a conductive filament. That is, an area in the film 202 that is not conductive. Since the cantilever tip 204 is not located at a filament, the capacitive (C₀) coupling between the cantilever 204 and the sample 202 dominates the current signal and the current signal may be give as:

$$i = ( {I}_{{C}_{0}} + {I}_{C} ) Sin ( ω t + \frac{π}{2} ) \approx {I}_{{C}_{0}} Sin ( ω t + \frac{π}{2} )$$

Where, the current signal is i, I_{C0} is the current of the capacitive coupling between the sample 202 and the cantilever arm 204, and I_{C} is the capacitive current through the film 202 between the cantilever tip 204 and the electrode 200 through the film 202. Since the probe or tip is not located at a conductive filament I_{C} may be negligible.

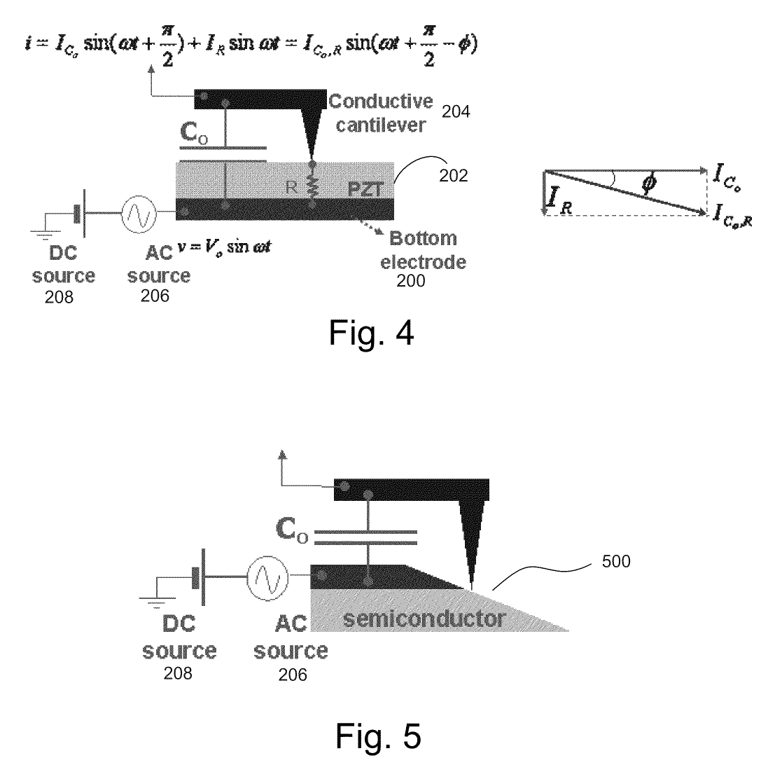

FIG. 4 is the set-up of FIG. 2 and FIG. 3 above, except that the cantilever 204 is now located at a conductive filament on the PZT film 202. Here. since the cantilever 204 is located at a filament, the current signal is a vector sum of the resistive current through the film 202 and the capacitive coupling current I_{C0} and may be given as:

$$i = {I}_{{C}_{0}} Sin ( ω t + \frac{π}{2} ) + {I}_{R} Sin ω t = {I}_{{C}_{0} , R} Sin ( ω t + \frac{π}{2} - φ )$$

Where, φ is the angle on the vector diagram between I_{C0} and I_{C0R} and w is the phase, and where the resistive current and the filament resistance are calculated based on the current signal vector diagram using:

$${I}_{R} = {I}_{{C}_{0}} tan φ ; and$$

$$R = \frac{{V}_{0}}{{I}_{R}}$$

Thus, if the current signal is of this nature, it can be determined that that area of the film 202 comprises a conductive filament.

Referring to FIG. 5, there is shown one embodiment for characterizing a semiconductor interface. As shown, to characterize a metal/semiconductor interface, the sample is polished to expose the interface 500. To further improve the resolution, the coupling current C₀ may be compensated with a suitable current at the amplifier. The DC and/or AC amplitudes and AC frequency can be changed to study changes of the interface 500 conduction characteristics.

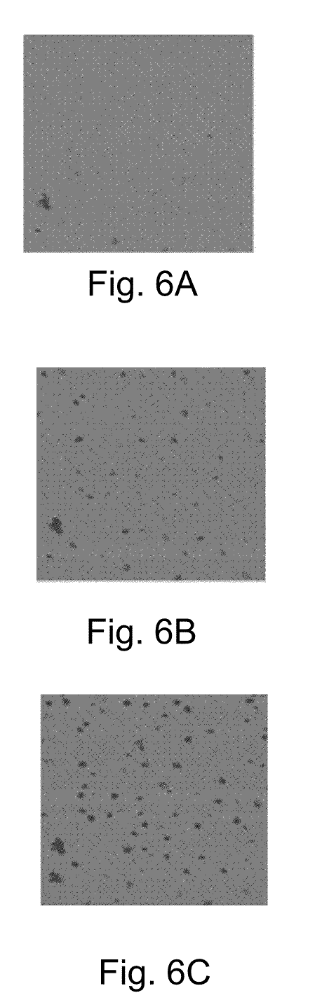

Embodiments may also be used to for a reading scheme for a resistance change memory by detecting conductive filaments. The same apparatus and scanning methods described above may be used; however the DC amplitude may be stepped incrementally while resistive current is recorded. Switching is detected as resistive current increases non-linearly. This is demonstrated in FIGS. 6A-C which shows a scanning impedance microscopy (SIM) image of a 1 um×1 um area on a PZT sample 202. FIG. 6A is the image when the DC source 208 is 1V and AC source amplitude is 250 mVp-p at 66 Hz.

In FIG. 6B, the DC source has been stepped up to 2V and AC source amplitude is 250 mVp-p at 66 Hz. Finally, FIG. 6C is the image when the DC source has been stepped to 3V and AC source amplitude is 250 mVp-p at 66 Hz. As the DC source is stepped up, more resistive filaments are switched.

Advantageously, the described scanning impedance microscopy described herein is relatively simple while provides nanometer resolution. Because the described Scanning Impedance Microscopy (SIM) technique maps out local impedance in a dielectric film with nanometer resolution, it can be used to detect conductive filaments in a PZT film, which provides valuable information for film development and retention study. Further, in additional to the high resolution provided by the invention, the scanning speed is much faster compared to the state of the art tunneling current (Atomic Force Microscopy) AFM methods with good signal to noise ratio and nanometer resolution. As a result, it is an attractive reading scheme for resistive change memory such as RRAM.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize.

These modifications can be made to the invention in light of the above detailed description. The terms used in the following claims should not be construed to limit the invention to the specific embodiments disclosed in the specification and the claims. Rather, the scope of the invention is to be determined entirely by the following claims, which are to be construed in accordance with established doctrines of claim interpretation.

What is claimed is:

1. An apparatus, comprising:
an alternating current (AC) source to apply an input current signal to a sample;
a conductive cantilever probe to scan over the sample;
a lock-in amplifier to compare the input current signal to a current signal detected by the probe to output a detected current phase signal and a detected current amplitude signal,
wherein the detected current phase signal and detected current amplitude signal are used to detect conductive filaments in the sample.

2. The apparatus as recited in claim 1, further comprising:
a direct current (DC) source connected to the AC current source.

3. The apparatus as recited in claim 1 wherein the sample comprises:
a bottom electrode connected to the AC current source; and
a dielectric film on the bottom electrode.

4. The apparatus as recited in claim 3 wherein the dielectric film comprises Lead Zirconate Titanate (PZT).

5. The apparatus as recited in claim 1 wherein the sample comprises:
a metal electrode connected to the AC current source; and
a semiconductor layer polished to reveal a metal/semiconductor interface.

6. The apparatus as recited in claim 1 wherein an area of the sample not comprising a conductive filament is detected by a current signal i characterized
$$i = ( {I}_{{C}_{0}} + {I}_{C} ) Sin ( ω t + \frac{π}{2} ) \approx {I}_{{C}_{0}} Sin ( ω t + \frac{π}{2} ) ;$$
where, I_{C0} is the current of capacitive coupling between the sample and the cantilever probe, and I_{C} is capacitive current through the sample at the cantilever probe tip.

7. The apparatus as recited in claim 1 wherein an area of the sample comprising a conductive filament is detected by a current signal i characterized by
$$i = {I}_{{C}_{0}} Sin ( ω t + \frac{π}{2} ) + {I}_{R} Sin ω t = {I}_{{C}_{0} , R} Sin ( ω t + \frac{π}{2} - φ )$$
where, φ is the angle on a vector diagram between I_{C0} and I_{C0R} and ω is the phase, and where the resistive current and the filament resistance are calculated based on the current signal vector diagram using
$${I}_{R} = {I}_{{C}_{0}} tan φ and R = \frac{{V}_{0}}{{I}_{R}} .$$

8. A method, comprising:
applying an input alternating current (AC) current signal to a sample;
scanning a conductive cantilever probe over the sample;
comparing the input current signal to a current signal detected by the probe to output a detected current phase signal and a detected current amplitude signal; and
determining conductive filaments in the sample with the detected current phase signal and detected current amplitude signal.

9. The method as recited in claim 8, further comprising:
biasing the input current signal with a direct current (DC) signal.

10. The method as recited in claim 8, wherein the sample comprises:
a bottom electrode connected to the AC current source; and
a dielectric film on the bottom electrode.

11. The method as recited in claim 10, wherein the dielectric film comprises Lead Zirconate Titanate (PZT).

12. The method as recited in claim 8, wherein the sample comprises:
a metal electrode connected to the AC current source; and
a semiconductor layer polished to reveal a metal/semiconductor interface.

13. The method as recited in claim 8, wherein an area of the sample not comprising a conductive filament is detected by a current signal i characterized by
$$i = ( {I}_{{C}_{0}} + {I}_{C} ) Sin ( ω t + \frac{π}{2} ) \approx {I}_{{C}_{0}} Sin ( ω t + \frac{π}{2} ) ;$$
where, I_{C0} is the current of capacitive coupling between the sample and the cantilever probe, and I_{C} is capacitive current through the sample at the cantilever probe tip.

14. The method as recited in claim 8, wherein an area of the sample comprising a conductive filament is detected by a current signal i characterized by
$$i = {I}_{{C}_{0}} Sin ( ω t + \frac{π}{2} ) + {I}_{R} Sin ω t = {I}_{{C}_{0} , R} Sin ( ω t + \frac{π}{2} - φ )$$
where, φ is the angle on a vector diagram between I_{C0} and I_{C0R} and ω is the phase, and where the resistive current and the filament resistance are calculated based on the current signal vector diagram using
$${I}_{R} = {I}_{{C}_{0}} tan φ and R = \frac{{V}_{0}}{{I}_{R}} .$$

15. A system for mapping local impedance of a dielectric film comprising:
an alternating current (AC) source to apply an input current signal to a sample comprising dielectric film;
a conductive cantilever probe to scan over the sample;
a lock-in amplifier to compare the input current signal to a current signal detected by the probe to output a detected current phase signal and a detected current amplitude signal,
wherein the detected current phase signal and detected current amplitude signal are used to detect conductive filaments in the sample; and
an output image for showing a mapping of the sample.

16. The system as recited in claim 15, further comprising:
a direct current (DC) source connected to the AC current source.

17. The system as recited in 15 wherein the sample comprises:
a bottom electrode connected to the AC current source; and
the dielectric film on the bottom electrode.

18. The system as recited in claim 17, wherein the dielectric film comprises Lead Zirconate Titanate (PZT).

19. The system as recited in claim 15, wherein an area of the sample not comprising a conductive filament is detected by a current signal i characterized by
$$i = ( {I}_{{C}_{0}} + {I}_{C} ) Sin ( ω t + \frac{π}{2} ) \approx {I}_{{C}_{0}} Sin ( ω t + \frac{π}{2} ) ;$$
where, I_{C0} is the current of capacitive coupling between the sample and the cantilever probe, and I_{C} is capacitive current through the sample at the cantilever probe tip.

20. The system as recited in claim 15, wherein an area of the sample comprising a conductive filament is detected by a current signal i characterized by
$$i = {I}_{{C}_{0}} Sin ( ω t + \frac{π}{2} ) + {I}_{R} Sin ω t = {I}_{{C}_{0} , R} Sin ( ω t + \frac{π}{2} - φ )$$
where, φ is the angle on a vector diagram between I_{C0} and I_{C0R} and ω is the phase, and where the resistive current and the filament resistance are calculated based on the current signal vector diagram using I_{R}=I_{C}_{₀} tan φ and
$$R = \frac{{V}_{0}}{{I}_{R}} .$$
